(19) United States
(12) Patent Application Publication
(10) Pub. No.: US 2008/0246077 A1
(43) Pub. Date: Oct. 9, 2008

(54) Method of fabricating semiconductor memory device and semiconductor memory device fabricated by the method

(75) Inventors: Young-Soo Park, Yongin-si (KR); Sam-Jong Choi, Suwon-si (KR); Kyoo-Chul Cho, Yongin-si (KR); Tae-Soo Kang, Seongnam-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/012,592

(22) Filed: Feb. 4, 2008

(30) Foreign Application Priority Data
Feb. 2, 2007 (KR) 10-2007-0010990

(51) Int. Cl. H01L 27/108; H01L 21/425

(52) U.S. Cl. 257/324; 438/530; 257/E29.309

(57) ABSTRACT

In a method for fabricating a semiconductor memory device and a semiconductor memory device fabricated by the method, the method includes forming a multi-layered dielectric structure including a first dielectric layer with an ion implantation layer and a second dielectric layer without an ion implantation layer, over a semiconductor substrate; forming nanocrystals in the first and second dielectric layers by diffusing ions of the ion implantation layer by thermally treating the multi-layered dielectric structure; and forming a gate electrode on the multi-layered dielectric structure.

### CROSS-REFERENCE TO RELATED APPLICATION

This application claims priority from Korean Patent Application No. 10-2007-0010990 filed on Feb. 2, 2007 in the Korean Intellectual Property Office, the disclosure of which is incorporated herein by reference in its entirety.

### BACKGROUND OF THE INVENTION

1. Field of the Invention

Embodiments of the present invention relate to a method for fabricating a semiconductor memory device and a semiconductor memory device fabricated by the method, and more particularly, to a method for fabricating a semiconductor memory device containing nanocrystals and a semiconductor memory device fabricated by the method.

2. Description of the Related Art

Semiconductor memory devices can generally be categorized as nonvolatile memory devices and volatile memory devices, depending on the storage state of data. In recent years, nonvolatile memory devices, which maintain data stored therein even if power is interrupted, have enjoyed a dramatic increase in use.

In a conventional nonvolatile memory device, a memory cell has a stacked structure including a tunnel oxide layer, a floating gate, a dielectric layer and a control gate sequentially formed in that order. In the memory cell having this structure, charge migrates through the tunnel oxide layer so that the charge can be stored in the floating gate, and a transistor is turned on/off in accordance with the quantity of charge stored in the floating gate.

In the conventional non-volatile semiconductor memory device, a leakage current can be generated due to defects occurring in the floating gate, which can be made of a conductive material, e.g., polysilicon. To solve this problem, research into a nonvolatile memory device utilizing a charge storage structure having nanocrystals in dispersed form is being conducted. In the nonvolatile memory device having nanocrystals, the nanocrystals are used as a charge storage device. Since the charge is stored in each of the dispersed nanocrystals, electron mobility may be restricted at inter-crystal regions.

The conventional non-volatile semiconductor memory device has higher charge retention capacity as the nanocrystal density increases. In addition, the operating voltage of the non-volatile semiconductor memory device becomes lower as the nanocrystal size becomes smaller. Accordingly, it is highly desirable to further reduce nanocrystal size while increasing the density per unit area.

### SUMMARY OF THE INVENTION

Embodiments of the present invention provide a method for fabricating a semiconductor memory device which can increase a density of nanocrystals.

Embodiments of the present invention also provide a semiconductor memory device fabricated in accordance with the method.

The above and other objects of the embodiments of the present invention will be described in or be apparent from the following description of the preferred embodiments.

According to one aspect, there is provided a method for fabricating a semiconductor memory device, the method including forming a multi-layered dielectric structure including a first dielectric layer with an ion implantation layer and a second dielectric layer without an ion implantation layer, over a semiconductor substrate, forming nanocrystals in the first and second dielectric layers by diffusing ions of the ion implantation layer by thermally treating the multi-layered dielectric structure, and forming a gate electrode on the multi-layered dielectric structure.

In one embodiment, forming of the multi-layered dielectric structure comprises sequentially forming the first dielectric layer and the second dielectric layer or the second dielectric layer and the first dielectric layer, on the semiconductor substrate.

In another embodiment, forming of the multi-layered dielectric structure comprises: forming the first dielectric layer on the semiconductor substrate; and forming the ion implantation layer by implanting semiconductor ions into a charge storage region of the first dielectric layer.

In another embodiment, the first dielectric layer and the second dielectric layer are formed to a thickness of about 1 to about 50 nm.

In another embodiment, the first dielectric layer and the second dielectric layer have different dielectric constants with respect to each other.

In another embodiment, the first dielectric layer and the second dielectric layer comprise at least one material selected from the group consisting of SiO₂, SiON, Al₂O₃, ZrO₂, HfO₂ and La₂O₃.

In another embodiment, the forming of the ion implantation layer comprises forming the ion implantation layer by implanting the semiconductor ions using silicon (Si) or germanium (Ge) ions into the first dielectric layer.

In another embodiment, the implanting of the semiconductor ions comprises performing implantation of the semiconductor ions such that the semiconductor ions are prevented from being implanted into the semiconductor substrate under the first dielectric layer.

In another embodiment, the implanting of the semiconductor ions comprises implanting the semiconductor ions to a depth of about 7 to about 10 nm.

In another embodiment, the implanting of the semiconductor ions comprises implanting the semiconductor ions with an ion implantation energy of about 1 to about 50 KeV.

In another embodiment, the thermally treating of the multi-layered dielectric structure is performed at a temperature of about 700 to about 900 C. for about 1 to about 60 minutes.

In another embodiment, the forming of the multi-layered dielectric structure further comprises forming a third dielectric layer including an ion implantation layer on the second dielectric layer without the ion implantation layer.

In another embodiment, the forming of the nanocrystals comprises forming the nanocrystals in the first through third dielectric layers by performing thermal treatment.

In another embodiment, after forming of the nanocrystals in the first and second dielectric layers, the method further comprises: forming a third dielectric layer on the second dielectric layer; forming an ion implantation layer by implanting semiconductor ions into a charge storage region of the third dielectric layer; and forming nanocrystals in the third dielectric layer by thermally treating the resultant product.

In another embodiment, the forming of the multi-layered dielectric structure comprises alternately stacking the first dielectric layer with the ion implantation layer and the second dielectric layer without the ion implantation layer.

In another aspect, a semiconductor memory device comprises: source/drain regions formed in a semiconductor substrate to be spaced apart from each other; a channel region disposed between the source/drain regions; a multi-layered dielectric structure having two or more dielectric layers stacked on the channel region; nanocrystals formed in the respective dielectric layers of the multi-layered dielectric structure; and a gate electrode formed on the multi-layered dielectric structure.

In one embodiment, the multi-layered dielectric structure is constructed such that adjacent dielectric layers are made of materials having different dielectric constants with respect to each other.

In another embodiment, the one or more dielectric layers comprise at least one material selected from the group consisting of SiO₂, SiON, Al₂O₃, ZrO₂, HfO₂ and La₂O₃.

In another embodiment, the respective dielectric layers of the multi-layered dielectric structure have a thickness of about 1 to about 50 nm.

In another embodiment, the nanocrystals are positioned at a central portion of each of the respective dielectric layers in the planar direction of the semiconductor substrate.

In another embodiment, the multi-layered dielectric structure includes first and second dielectric layers sequentially stacked, and wherein the density of the nanocrystals formed in the first dielectric layer is higher than that of the nanocrystals formed in the second dielectric layer.

In another embodiment, the nanocrystals in the first dielectric layer are positioned to be spaced about 1 to about 7 nm apart from a surface of the semiconductor substrate.

In another embodiment, the nanocrystals are silicon (Si) or germanium (Ge) nanocrystals.

### BRIEF DESCRIPTION OF THE DRAWINGS

The above and other features and advantages of the embodiments of the present invention will become more apparent by describing in detail preferred embodiments thereof with reference to the attached drawings in which:

FIGS. 1 through 3 are cross-sectional views of semiconductor memory devices according to embodiments of the present invention;

FIGS. 4A through 4E are cross-sectional views illustrating a method for fabricating a semiconductor memory device according to an exemplary embodiment of the present invention, as shown in FIG. 1;

FIGS. 5A through 5F are cross-sectional views illustrating a method for fabricating a semiconductor memory device according to another exemplary embodiment of the present invention, as shown in FIG. 2;

FIGS. 6A through 6H are cross-sectional views illustrating a modified example of the method for fabricating a semiconductor memory device according to another embodiment of the present invention, as shown in FIG. 2;

FIGS. 7A through 7H are cross-sectional views illustrating a method for fabricating a semiconductor memory device according to still another exemplary embodiment of the present invention, as shown in FIG. 3; and

FIG. 8 is a graph illustrating a capacitance-voltage (C-V) characteristic of a semiconductor memory device according to an embodiment of the present invention.

### DETAILED DESCRIPTION OF EMBODIMENTS

Advantages and features of the embodiments of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art. Like reference numerals refer to like elements throughout the specification.

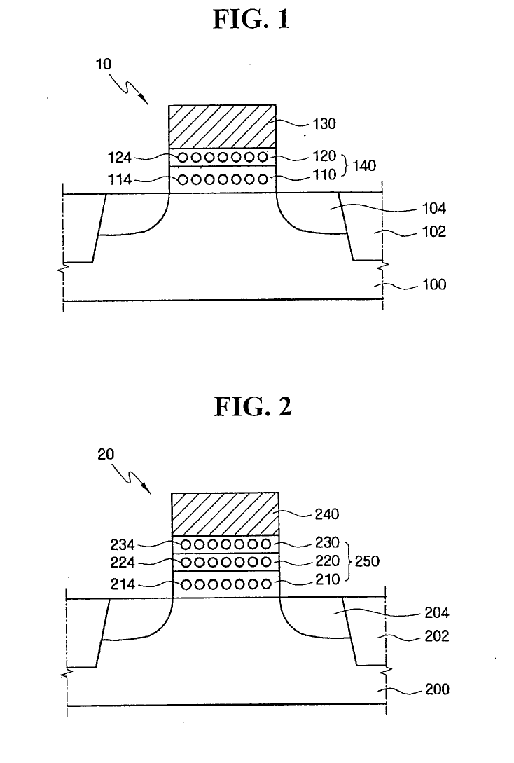

Structures of semiconductor memory devices according to embodiments of the present invention will first be described with reference to FIGS. 1 through 3. FIGS. 1 through 3 are cross-sectional views of semiconductor memory devices according to embodiments of the present invention.

As shown in FIGS. 1 through 3, an active region is defined by a device isolation film 102, 202, 302 formed on a predetermined region of a semiconductor substrate 100, 200, 300, respectively. Source/drain regions 104, 204, 304, formed by impurity implantation, are spaced apart from each other in the active region. A channel region is formed between the source/drain regions 104, 204, 304.

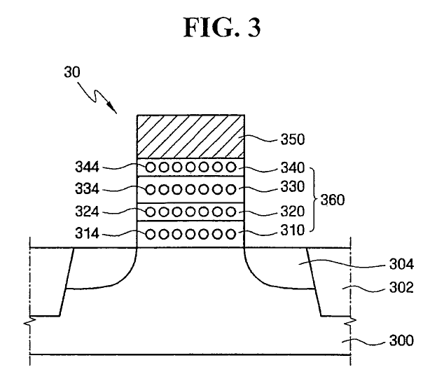

Multi-layered dielectric structures 140, 250 and 360 having one or more stacked dielectric layers are disposed over the channel regions of the semiconductor substrates 100, 200 and 300. According to various embodiments of the present invention, the dielectric structures 140, 250 and 360 may have a two-layered structure having first and second dielectric layers 110 and 120 stacked therein, as shown in FIG. 1, a three-layered structure having first, second and third dielectric layers 210, 220 and 230 stacked therein, as shown in FIG. 2, or a four-layered structure having first, second, third and fourth dielectric layers 310, 320, 330 and 340 stacked therein, as shown in FIG. 3.

Each dielectric layer can comprise a high-k material, for example, SiO₂, SiON, Al₂O₃, ZrO₂, HfO₂ or La₂O₃. The respective dielectric layers are formed to a thickness in the range of about 1 to about 50 nm, and thicknesses of the respective dielectric layers may be the same as or different from one another.

The respective dielectric layers 110, 120, 210, 220, 230, 310, 320, 330 and 340 of the corresponding multi-layered dielectric structures 140, 250 and 360 have multiple nanocrystals 114, 124, 214, 224, 234, 314, 324, 334 and 344 therein as trap sites for storing charge.

Since the multiple nanocrystals 114, 124, 214, 224, 234, 314, 324, 334 and 344 are disposed in the multi-layered dielectric structures 140, 250 and 360, a reduction in the number of nanocrystals due to a reduced width of a dielectric layer caused by a reduction in the design rule can be avoided. In addition, as the number of dielectric layers in a multi-layered dielectric structure increases, an area of the multi-layered dielectric structure where nanocrystals are positioned can be increased, thereby increasing the resulting density of trap sites.

Positions and configurations of nanocrystals placed in each dielectric layer are generally the same as or similar in the first through third embodiments. Hereinafter, nanocrystals will be representatively described with regard to a semiconductor memory device according to a first embodiment of the present invention with reference to FIG. 1.

In other words, nanocrystals 114 and 124 in the respective dielectric layers 110 and 120 have a size of about 1 to about 5 μm, and may be positioned at, for example, central regions of the respective dielectric layers 110 and 120 in the planar direction. In more detail, the nanocrystals 114 and 124 can be positioned to cover an area corresponding to a depth of about ¼ to about ¾ the thickness of each of the dielectric layers 110 and 120, and the nanocrystals 114 and 124 can be enclosed in the dielectric layers 110 and 120. Here, the nanocrystals 114 and 124 can, for example, be silicon (Si) nanocrystals or germanium (Ge) nanocrystals.

Portions of the first dielectric layer 110 disposed between the respective nanocrystals 114 in the first dielectric layer 110 serve as tunneling insulators. Accordingly, the nanocrystals 114 in the first dielectric layer 110 may be spaced about 1 to about 7 nm apart from a surface of the semiconductor substrate 100.

In the aforementioned semiconductor memory devices, in the event a predetermined voltage is applied to a gate electrode, charge present the channel region tunnels into the first dielectric layer 110, 210, 310 in contact with the semiconductor substrate 100, 200, 300 and is trapped by the nanocrystals in each dielectric layer 110, 210, 310. An electric field applied when charge in the channel region is trapped by nanocrystals and an electric field applied when charge in the channel region is not trapped by nanocrystals will be different. Accordingly, the different electric fields may affect the channel region, thereby varying a threshold voltage of the semiconductor memory device. The semiconductor memory device can perform write and read operations using the threshold voltage that varies when charge is trapped and when not trapped in the trap site.

The semiconductor memory devices according to embodiments of the present invention have multi-layered dielectric structures 140, 250, 360 each having one or more dielectric layers. Since each dielectric layer contains nanocrystals, the density of trap sites for storing charge can be increased even in the even that the design rule of a semiconductor memory device is continuously scaled down.

Accordingly, when a semiconductor memory device operates at a high voltage, the charge storage stability can be significantly enhanced, and a relatively wide memory window can be obtained so that data is recognizable over a wide range of operating voltages of the semiconductor memory device.

Hereinafter, methods for fabricating semiconductor memory devices according to a few embodiments of the present invention will be described.

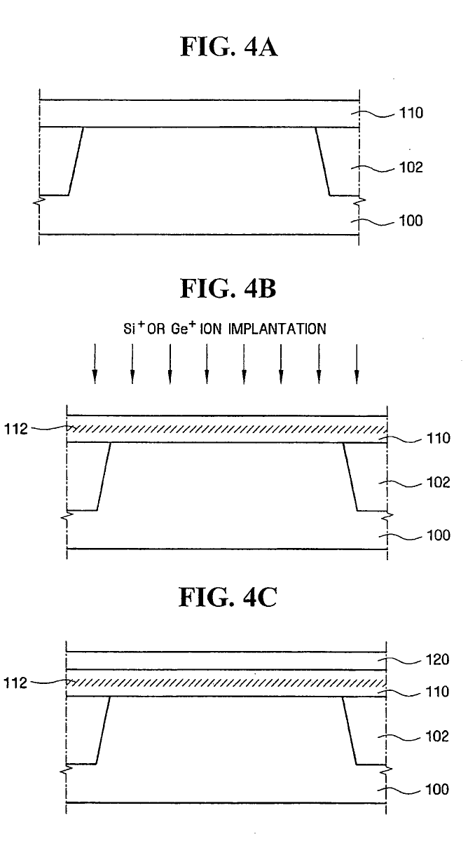

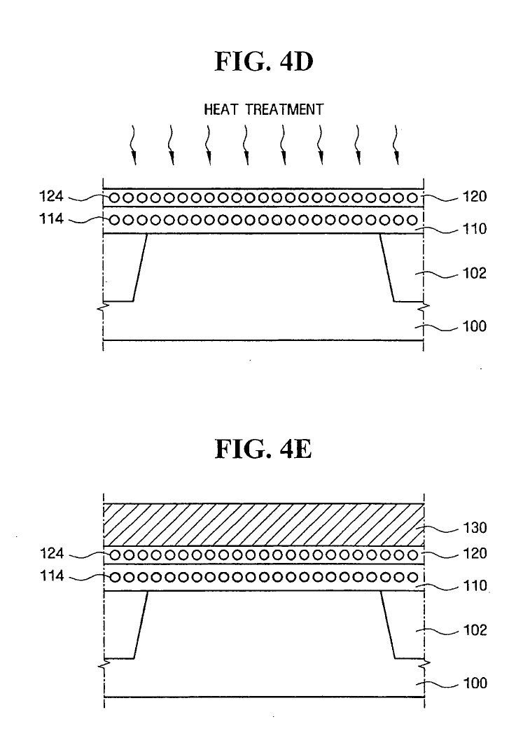

A method for fabricating a semiconductor memory device according to an exemplary embodiment of the present invention will first be described with reference to FIGS. 4A through 4E. FIGS. 4A through 4E are cross-sectional views sequentially illustrating a method for fabricating a semiconductor memory device according to an exemplary embodiment of the present invention, as shown in FIG. 1.

Referring first to FIG. 4A, a semiconductor substrate 100 is provided, and a device isolation process for defining an active region and a field region is performed on the semiconductor substrate 100 to form a device isolation film 102. The device isolation process may be performed by employing a shallow trench isolation (STI) method or a local oxidation of silicon (LOCOS) method.

Then, a first insulating layer 110 is formed on the semiconductor substrate 100 having the device isolation film 102. Here, the first insulating layer 110 may be formed using, but not limited to, silicon dioxide (SiO₂), a high dielectric constant (high-k) material, such as SiON, Al₂O₃, ZrO₂, HfO₂, or La₂O₃, and the like. The first insulating layer 110 may be formed to a thickness of about 1 to about 50 nm.

As shown in FIG. 4B, an ion implantation layer 112 is formed by implanting semiconductor ions into a charge storage region of the first dielectric layer 110. The semiconductor ions implanted into the first dielectric layer 110 may comprise, for example, silicon (Si) or germanium (Ge) ions.

The ion implantation layer 112 formed by implanting the semiconductor ions determines a thickness of a tunnel oxide. Thus, the ion implantation process may be performed such that the semiconductor ions are implanted into the first dielectric layer 110 so they are spaced apart from a surface of the semiconductor substrate 100. That is to say, the ion implantation layer 112 is formed at a depth of about half the thickness of the first dielectric layer 110. That is, the ion implantation layer 112 is formed at a depth of about ¼ to about ¾ the thickness of the first dielectric layer 110. Specifically, the semiconductor ions may be implanted into a region or depth, for example, which is spaced about 1 to about 7 nm apart from the surface of the semiconductor substrate 100.

In order to form the ion implantation layer 112 at the central area of the first dielectric layer 110, the semiconductor ions may be implanted with an ion implantation energy of, e.g., about 1 to about 50 KeV.

As shown in FIG. 4C, the second dielectric layer 120 is formed on the first dielectric layer 110 having the ion implantation layer 112. Here, the second dielectric layer 120 is made of a material having a different dielectric constant from that of the first dielectric layer 110 disposed under the second dielectric layer 120. For example, the second dielectric layer 120 may be formed of aluminum oxide (Al₂O₃) or a high-k material such as SiO₂, SiON, ZrO₂, HfO₂ or La₂O₃. Here, the second dielectric layer 120 is formed to a thickness of about 1 to about 50 nm, and can be thinner than the first dielectric layer 110 disposed thereunder.

After forming the first and second layers 110 and 120, the resultant product is thermally treated. Here, the thermal treatment may be performed at a temperature of about 700 to about 900 C. for about 1 to about 60 minutes.

As a result, as shown in FIG. 4D, the semiconductor ions of the ion implantation layer 112 formed in the first dielectric layer 110 are crystallized to form nanocrystals 114. At the same time, as the thermal treatment proceeds, some of the semiconductor ions of the ion implantation layer 112 formed in the first dielectric layer 110 may be diffused into the second dielectric layer 120 disposed over the first dielectric layer 110. Accordingly, in addition to the nanocrystals 114 formed in the first dielectric layer 110, nanocrystals 124 are also formed in the second dielectric layer 120. The thus-formed nanocrystals 114 and 124 are formed in the respective dielectric layers 110 and 120 such that nano-sized crystals having a size of about 1 to about 5 nm are spaced apart from one another.

Here, conditions of the thermal treatment for forming the nanocrystals 114 and 124 in the first dielectric layer 110 and the second dielectric layer 120 using the ion implantation layer 112 formed in the first dielectric layer 110 may vary according to the size and characteristics of the semiconductor memory device.

While the previous embodiment has been described with reference to the ion implantation layer 112 formed in the first dielectric layer 110, the invention is not limited thereto. That is, an ion implantation layer may also be formed in the second dielectric layer 120 and nanocrystals may be formed in the first and second dielectric layers, respectively, by performing thermal treatment.

Since the nanocrystals 114 and 124 can be formed in the second dielectric layer 120 as well as in the first dielectric layer 110, as described above, the density of nanocrystals can be increased within a limited design rule.

Next, a conductive layer 130 for forming a gate electrode may be formed of a single layer made of doped polysilicon, a metallic material such as W, Pt, Ru or Ir, a conductive metal nitride such as TiN, TaN or WN, a conductive metal oxide such as RuO₂ or IrO₂, or a stacked layer made of combinations of these materials.

Next, as shown in FIG. 1, the first and second layers 110 and 120 and the conductive layer 130 stacked on the semiconductor substrate 100 are patterned, thereby completing the gate electrode.

Impurity ions are implanted into the semiconductor substrate 100 at opposite sides of the gate electrode to form source and drain regions 104, thereby completing the semiconductor memory device 10 according to an embodiment of the present invention, as shown in FIG. 1.

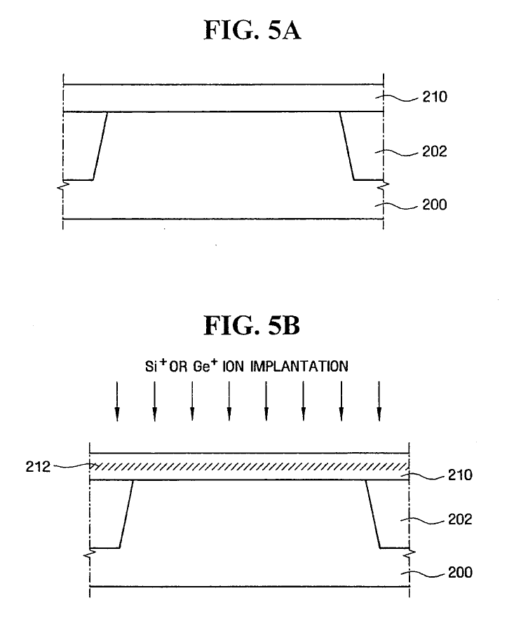

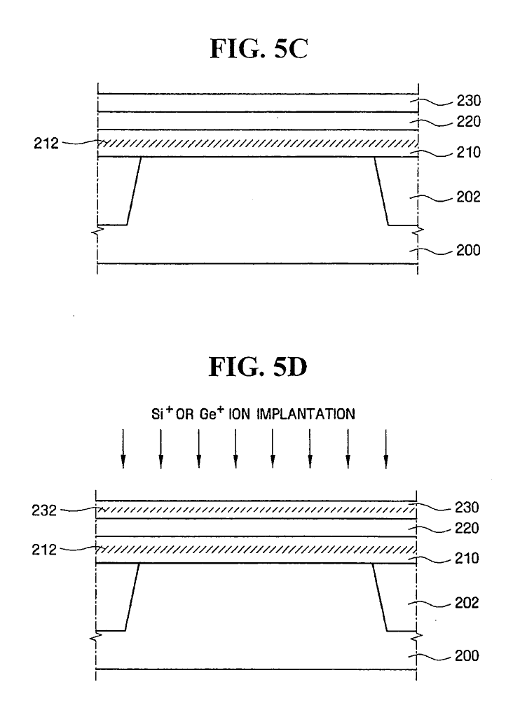

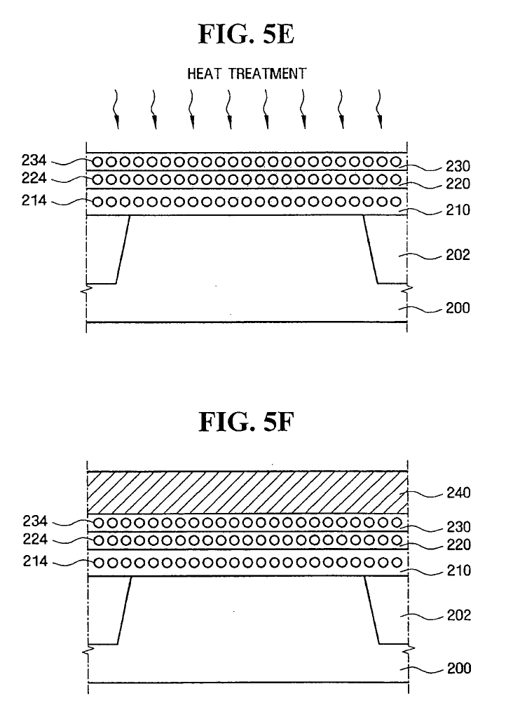

Next, a method for fabricating a semiconductor memory device according to another exemplary embodiment of the present invention will be described with reference to FIGS. 5A through 5F. FIGS. 5A through 5F are cross-sectional views illustrating a method for fabricating a semiconductor memory device according to another exemplary embodiment of the present invention, as shown in FIG. 2. Unlike the previous embodiment, the current embodiment describes a multi-layered dielectric structure including three dielectric layers.

As shown in FIG. 5A, a device isolation film 202 is formed in a semiconductor substrate 200 to define an active region. Then, a first dielectric layer 210 is formed on the semiconductor substrate 200. Here, the first dielectric layer 210 may be formed of silicon dioxide (SiO₂), or a high dielectric constant (high-k) material, such as SiON, Al₂O₃, ZrO₂, HfO₂, or La₂O₃. Here, the first insulating layer 210 may be formed to a thickness of about 1 to about 50 nm.

As shown in FIG. 5B, an ion implantation layer 212 is formed by implanting semiconductor ions into a charge storage region of the first dielectric layer 210. The semiconductor ions implanted into the first dielectric layer 210 may be, for example, silicon (Si) or germanium (Ge) ions, like in the previous embodiment.

Locations at which the implantation layer 212 is formed and various processing conditions are the same as those of the previous embodiment, and a detailed explanation will not be given.

Next, as shown in FIG. 5C, a second dielectric layer 220 and a third dielectric layer 230 are sequentially formed on the first dielectric layer 210 having the ion implantation layer 212. The second dielectric layer 220 is made of a material having a different dielectric constant from that of the first dielectric layer 210, and the third dielectric layer 230 is made of a material having a different dielectric constant from that of the second dielectric layer 220. For example, the second dielectric layer 220 may be formed of aluminum oxide (Al₂O₃) and the third dielectric layer 230 may be formed of silicon oxide (SiO₂). Alternatively, the second and third dielectric layers 220 and 230 may be formed of another high-k material such as SiON, Al₂O₃, ZrO₂, HfO₂ or La₂O₃.

Here, the second and third dielectric layer 220 and 230 are formed to a thickness of about 1 to about 50 nm, and may be thinner than the first dielectric layer 210 disposed thereunder.

Thereafter, as shown in FIG. 5D, semiconductor ions are implanted into a predetermined area of the third dielectric layer 230 positioned on top of the multi-layered dielectric structure, thereby forming an ion implantation layer 232 in the third dielectric layer 230.

Next, the resultant product is thermally treated to form nanocrystals 214, 224 and 234 in the first through third dielectric layers 210, 220 and 230, respectively, as shown in FIG. 5E.

Specifically, during the thermal treatment, the semiconductor ions of ion implantation layers 212 and 232 formed in the first and third dielectric layers 210 and 230 are crystallized to form the nanocrystals 214 and 234. At the same time, some of the semiconductor ions of the ion implantation layers 212 and 232 formed in the first and third dielectric layers 210 and 230 may be diffused into the second dielectric layer 220. Accordingly, semiconductor ions are crystallized in the second dielectric layer 220 as well to form the nanocrystals 224.

The thermal treatment may be performed in a chamber maintained in a nitrogen (N₂) or argon (Ar) at a temperature of about 700 to about 900 C. for about 1 to about 60 minutes. These processing conditions may vary according to parameters such as a diffusion speed of semiconductor ions or a crystallization speed.

As shown in FIG. 5F, a conductive layer 240 for forming a gate electrode is formed on the third dielectric layer 230, and the resultant product on the semiconductor substrate 200 is patterned, thereby completing the gate electrode. Subsequently, source and drain regions 204 are formed in the semiconductor substrate 100 at opposite sides of the gate electrode to form, thereby completing the semiconductor memory device 20 shown in FIG. 2.

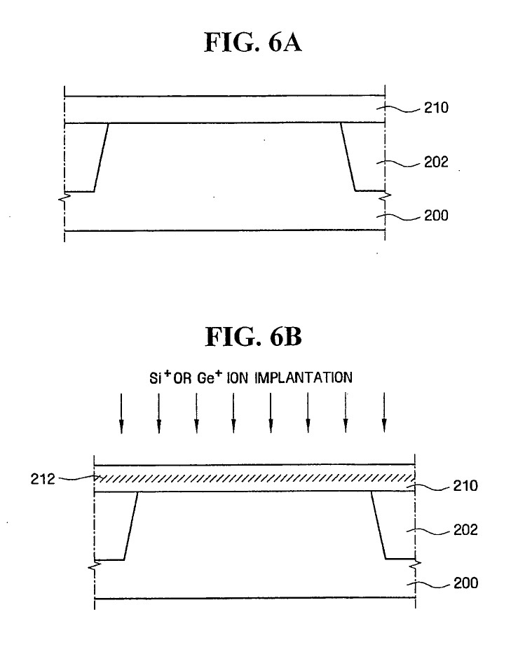

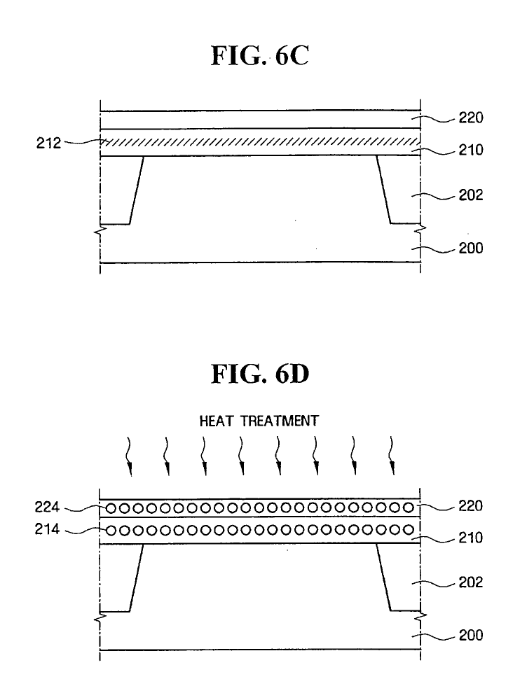

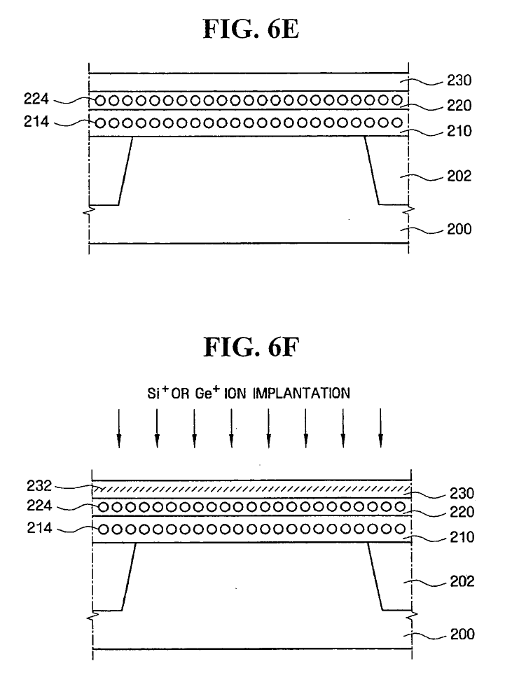

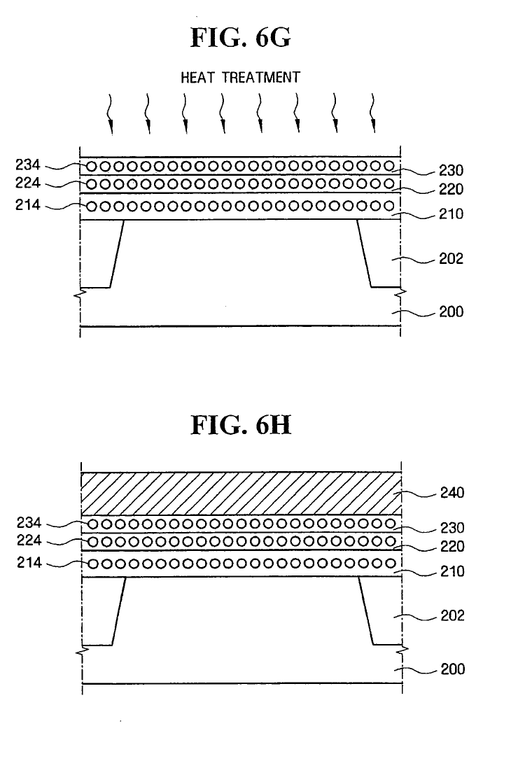

Next, a method for fabricating a semiconductor memory device according to a modified embodiment of the present invention will be described with reference to FIGS. 6A through 6H. FIGS. 6A through 6H a are cross-sectional views illustrating a modified example of the method for fabricating a semiconductor memory device according to another embodiment of the present invention, as shown in FIG. 2.

First, as shown in FIG. 6A, a first insulating layer 210 is formed on a semiconductor substrate 200 having an active region defined by a device isolation film 202. Here, the first insulating layer 210 is formed of a high-k material to a thickness of about 1 to about 50 nm.

Then, as shown in FIG. 6B, an ion implantation layer 212 is formed in the first dielectric layer 210. As described above, as semiconductor ions of the ion implantation layer 212, silicon (Si) or germanium (Ge) ions may be implanted into the first dielectric layer 210. Here, the ion implantation process is performed in consideration of a thickness of a tunnel oxide layer of a semiconductor memory device. That is to say, the ion implantation layer 212 is formed by implanting the semiconductor ions into the first insulating layer 210 at a region or depth which is spaced about 1 to about 5 nm apart from a surface of the semiconductor substrate 200.

Thereafter, as shown in FIG. 6C, a second dielectric layer 220 is formed on the first dielectric layer 210. The second dielectric layer 220 is made of a material having a different dielectric constant from that of the first dielectric layer 210, and may be thinner than the first dielectric layer 210.

Thereafter, as shown in FIG. 6D, the resultant product is thermally treated. Conditions for the thermal treatment are the same as those of the embodiment shown in FIGS. 4A through 4E. Accordingly, the semiconductor ions of the ion implantation layer 212 formed in the first dielectric layer 210, are crystallized to form nanocrystals 214. At the same time, the semiconductor ions of the ion implantation layer 212 formed in the first dielectric layer 210 are diffused into the second dielectric layer 220, so that nanocrystals 224 may be formed in a predetermined area of the second dielectric layer 220 as well.

Subsequently, as shown in FIG. 6E, a third dielectric layer 230 is formed on the second dielectric layer 220 having the nanocrystals 224 formed therein. The third dielectric layer 230 is made of a material having a different dielectric constant from that of the second dielectric layer 220. For example, the third dielectric layer 230 may be formed of a high-k material such as SiO₂, SiON, Al₂O₃, ZrO₂, HfO₂ or La₂O₃. In addition, the third dielectric layer 230 may be formed to a thickness in the range of about 1 to about 50 nm, and may be thinner than the first dielectric layer 210.

Next, as shown in FIG. 6F, semiconductor ions are implanted into the third dielectric layer 230, thereby forming an ion implantation layer 232 of the third dielectric layer 230. During the ion implantation process, ion implanting conditions are adjusted such that the semiconductor ions are positioned at a central region of the third dielectric layer 230 in the planar direction.

Subsequently, as shown in FIG. 6G, the resultant product is thermally treated, thereby forming nanocrystals in the third dielectric layer 230 as well. During the thermal treatment, temperature and time conditions are adjusted to allow the semiconductor ions present in the ion implantation layer 232 of the third dielectric layer 230 to be crystallized.

As a result, the respective nanocrystals 214, 224 and 234 can be formed in the first through third dielectric layers 210, 220 and 230. Accordingly, the density of trap sites of the semiconductor memory device can be increased.

Next, as shown in FIG. 6H, a conductive layer 240 for forming a gate electrode is formed on the third dielectric layer 230 and various structures stacked on the semiconductor substrate 200 are sequentially are patterned, thereby completing the gate electrode. Subsequently, impurities are doped into the semiconductor substrate 200 at opposite sides of the gate electrode to form source and drain regions 204, thereby completing the modified example of the semiconductor memory device 20 shown in FIG. 2.

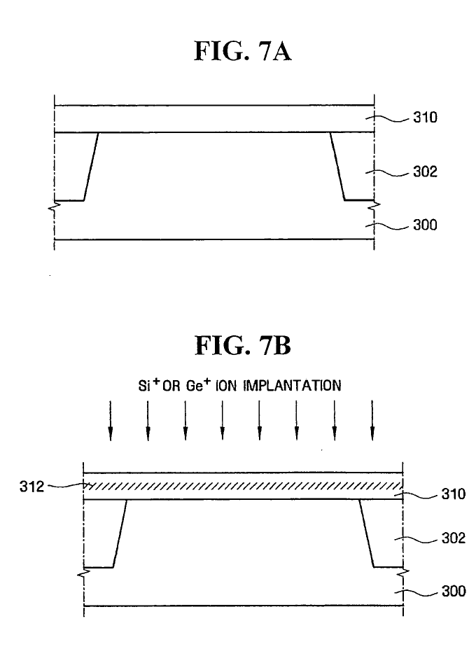

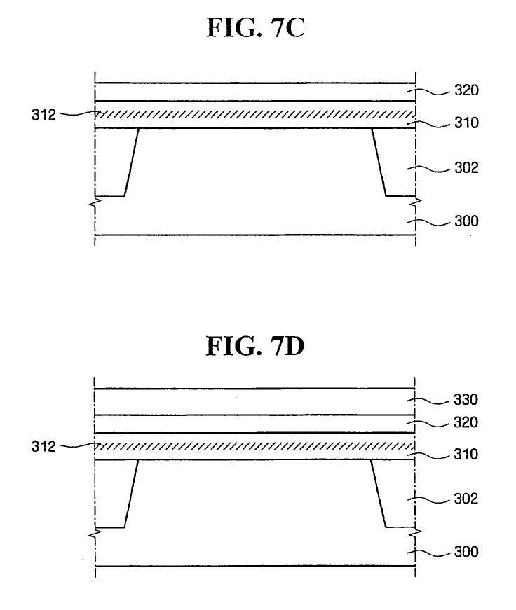

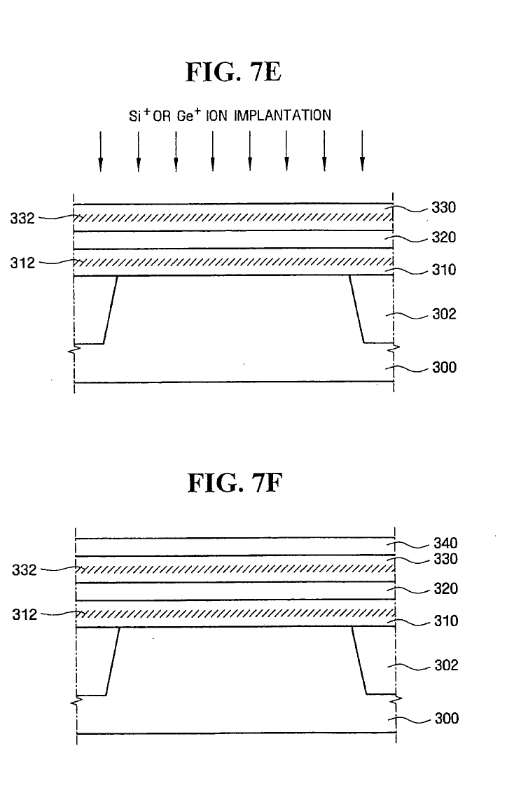

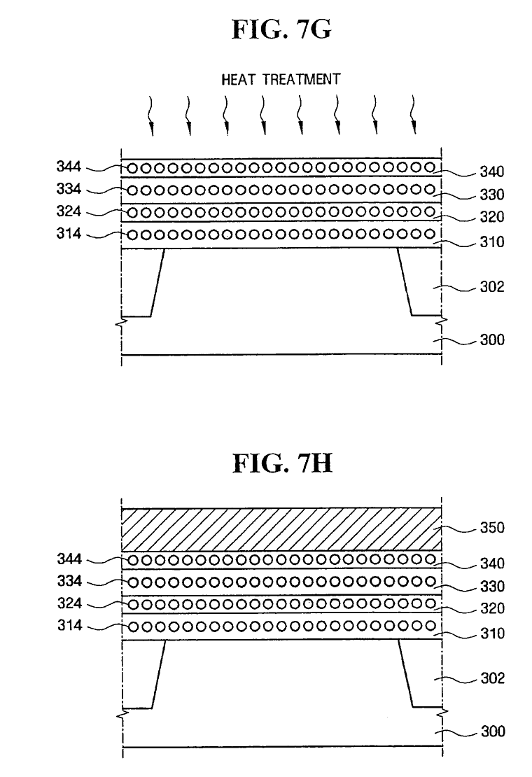

Next, a method for fabricating a semiconductor memory device according to a still another embodiment of the present invention will be described with reference to FIGS. 7A through 7H. FIGS. 7A through 7H are cross-sectional views sequentially illustrating a method for fabricating a semiconductor memory device according to a still another embodiment of the present invention, as shown in FIG. 3.

As shown in FIG. 7A, a device isolation film 302 is formed in a semiconductor substrate 300 to define an active region, and then a first dielectric layer 310 is formed on the semiconductor substrate 300. Here, the first dielectric layer 310 may be formed of silicon dioxide (SiO₂) and may be formed to a thickness of about 1 to about 50 nm.

As shown in FIG. 7B, an ion implantation layer 312 is formed by implanting semiconductor ions into a charge storage region of the first dielectric layer 310. Here, the ion implantation layer 312 may be formed by implanting silicon (Si) or germanium (Ge) ions into an region that is a predetermined distance spaced apart from a surface from the semiconductor substrate 300. For example, the ion implantation layer 312 may be formed in a region about 1 to about 5 nm spaced apart from the surface from the semiconductor substrate 300.

Portions of the first dielectric layer 310 disposed between the ion implantation layer 312 and the semiconductor substrate 300 serve as tunneling insulators of the semiconductor memory device.

Next, as shown in FIG. 7C, a second dielectric layer 320 is formed on the first dielectric layer 310 having the ion implantation layer 312. The second dielectric layer 320 is made of a material having a different dielectric constant from that of the first dielectric layer 310. For example, the second dielectric layer 320 may be formed of aluminum oxide (Al₂O₃). In addition, the second dielectric layer 320 may be formed to a thickness in the range of about 1 to about 50 nm, and may be thinner than the first dielectric layer 310.

Thereafter, the processes shown in FIGS. 7A through 7C are repeatedly performed on the second dielectric layer 230 to form third and fourth dielectric layers 330 and 340.

In detail, as shown in FIG. 7D, the third dielectric layer 330, which is made of a material having a different dielectric constant from that of the second dielectric layer 320, is formed on the second dielectric layer 320.

Then, as shown in FIG. 7E, semiconductor ions are implanted into the third dielectric layer 330, thereby forming an ion implantation layer 332. Here, ion implanting conditions are adjusted such that the ion implantation layer 332 is positioned at a central area of the third dielectric layer 330 in the planar direction.

As shown in FIG. 7F, the fourth dielectric layer 330 is formed on the third dielectric layer 330 using a material having a different dielectric constant from that of the third dielectric layer 330.

As described above, when forming the first through fourth dielectric layers 310 through 340, the respective dielectric layers are made of a high-k material such as SiO₂, SiON, Al₂O₃, ZrO₂, HfO₂ or La₂O₃. In addition, adjacent dielectric layers may be made of materials having different dielectric constants relative to each other.

Thereafter, as shown in FIG. 7G, the resultant product is thermally treated. Here, the thermal treatment may be performed at a chamber maintained in a nitrogen (N₂) or argon (Ar) atmosphere at a temperature of about 700 to about 900 C for about 1 to about 60 minutes.

As a result, the semiconductor ions of the ion implantation layers 312 and 332 formed in the first and third dielectric layers 310 and 330 are crystallized, thereby forming nanocrystals 314 and 334. In addition, the thermal treatment allows the semiconductor ions of the ion implantation layers 312 and 332 formed in the first and third dielectric layers 310 and 330 to be diffused into the second and fourth dielectric layers 320 and 340 adjacent to the first and third dielectric layers 310 and 330. Accordingly, the semiconductor ions diffused into the second and fourth dielectric layers 320 and 340 are also crystallized, so that nanocrystals 324 and 344 may be formed in the second and fourth dielectric layers 320 and 340 as well.

The nanocrystals 312, 324, 334 and 344 are respectively formed in the first through fourth dielectric layers 310 through 340 such that nano-sized crystals having a size of about 1 to about 5 nm are spaced apart from one another.

Accordingly, since the nanocrystals 314, 324, 334 and 334 can be formed in each of the first through fourth dielectric layers 310 through 340 constituting a multi-layered dielectric structure, the density of nanocrystals in the resulting dielectric structure can be increased.

Thereafter, a conductive layer 350 for forming a gate electrode is formed on the fourth dielectric layer 340, and various dielectric layers and the conductive layer 350 are patterned, thereby completing the gate electrode. Subsequently, source and drain regions 304 are formed in the semiconductor substrate 300 at opposite sides of the gate electrode to form source and drain regions 304, thereby completing the semiconductor memory device 30 shown in FIG. 3.

While the exemplary embodiments have been described with reference to the ion implantation layers formed in the first through third dielectric layers, the invention is not limited thereto. That is, ion implantation layers may be formed in various types of combinations under conditions in which nanocrystals can be formed. For example, ion implantation layers may be formed in second and fourth dielectric layers or in first and fourth dielectric layers. Other combinations of layers are also possible.

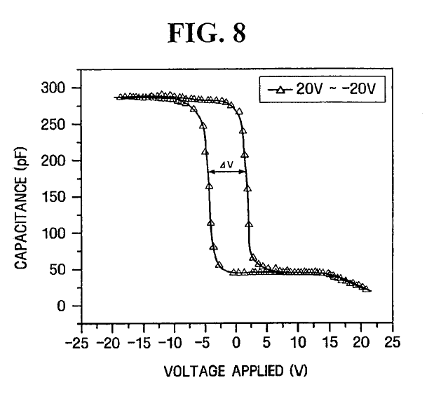

An exemplary experiment was carried out on a semiconductor memory device according to an embodiment of the present invention and the result thereof will be described with reference to FIG. 8.

In this exemplary experiment, a first dielectric layer is formed of a silicon oxide (SiO₂) layer having a thickness of about 17 nm on a semiconductor substrate, and an ion implantation layer is formed by implanting germanium (Ge) ions with an implantation energy of about 10 KeV. Then, a second dielectric layer is formed of an aluminum oxide (Al₂O₃) layer having a thickness of about 7 nm on the first dielectric layer. The entire resultant structure is subjected to thermal treatment in a nitrogen (N₂) atmosphere at a temperature of about 80° C. for about 30 minutes, thereby completing the semiconductor memory device having nanocrystals in the first and second dielectric layers. Then, a current-voltage characteristic (hereinafter, “a C-V characteristic”) of the completed semiconductor memory device is tested.

For measurement of the C-V characteristic of the semiconductor memory device, during a programming operation, +20 V is applied to a gate electrode and storage capacity is measured while varying the voltage applied to the gate electrode to measure a flat band voltage. During an erasing operation, −20 V is applied to the gate electrode and storage capacity is measured while varying the voltage applied to the gate electrode. A memory window of a semiconductor memory device, that is, a change in the flat band voltage, can be obtained by measuring the flat band voltages at +20 V and −20 V.

The result of this experiment is illustrated in FIG. 8. FIG. 8 is a graph illustrating a capacitance-voltage (C-V) characteristic of a semiconductor memory device according to an embodiment of the present invention.

Referring to FIG. 8, the semiconductor memory device according to an embodiment of the present invention has a memory window of about 10 V during a programming or erasing operation at ±20V. In other words, according to the present invention, a relatively high memory window, i.e., about 10 V, can be obtained, compared with that of the conventional art, i.e., about 1.0 to 3.5 V. Therefore, the semiconductor memory device according to an embodiment of the present invention containing nanocrystals in each of multiple dielectric layers constituting a multi-layered dielectric structure can increase the density of the trap sites, thereby increasing the memory window. Accordingly, during programming and/or erasing operations, data can be recognized over a wider range of operating voltages of the semiconductor memory device.

As described above, since a semiconductor memory device according to the present invention has a multi-layered dielectric structure having one or more dielectric layers, each containing nanocrystals, a reduction in the number of nanocrystals, resulting from a reduction in the width of each of the one or more dielectric layers due to continuous scaling down, can be avoided.

In addition, since an area of a multilayered dielectric structure, where nanocrystals are positioned, is considerably increased, the density of trap sites for storing charge can be increased even if a design rule of a semiconductor memory device is continuously scaled down.

Accordingly, interference between charge stored in the nanocrystals can be reduced. In addition, when the semiconductor memory device operates at a high voltage, the charge storage stability can be significantly enhanced, and a relatively wide memory window can be obtained so that data is recognizable over a wide range of operating voltages of the semiconductor memory device.

While the present invention has been particularly shown and described with reference to exemplary embodiments thereof, it will be understood by those of ordinary skill in the art that various changes in form and details may be made herein without departing from the spirit and scope of the present invention as defined by the following claims. It is therefore desired that the present embodiments be considered in all respects as illustrative and not restrictive.

What is claimed is:

1. A method for fabricating a semiconductor memory device, the method comprising:
forming a multi-layered dielectric structure including a first dielectric layer with an ion implantation layer and a second dielectric layer without an ion implantation layer, over a semiconductor substrate;
forming nanocrystals in the first and second dielectric layers by diffusing ions of the ion implantation layer by thermally treating the multi-layered dielectric structure; and
forming a gate electrode on the multi-layered dielectric structure.

2. The method of claim 1, wherein the forming of the multi-layered dielectric structure comprises sequentially forming the first dielectric layer and the second dielectric layer or the second dielectric layer and the first dielectric layer, on the semiconductor substrate.

3. The method of claim 2, wherein the forming of the multi-layered dielectric structure comprises:
forming the first dielectric layer on the semiconductor substrate; and
forming the ion implantation layer by implanting semiconductor ions into a charge storage region of the first dielectric layer.

4. The method of claim 3, wherein the first dielectric layer and the second dielectric layer are formed to a thickness of about 1 to about 50 nm.

5. The method of claim 3, wherein the first dielectric layer and the second dielectric layer have different dielectric constants with respect to each other.

6. The method of claim 5, wherein the first dielectric layer and the second dielectric layer comprise at least one material selected from the group consisting of SiO₂, SiON, Al₂O₃, ZrO₂, HfO₂ and La₂O₃.

7. The method of claim 3, wherein the forming of the ion implantation layer comprises forming the ion implantation layer by implanting the semiconductor ions using silicon (Si) or germanium (Ge) ions into the first dielectric layer.

8. The method of claim 7, wherein the implanting of the semiconductor ions comprises performing implantation of the semiconductor ions such that the semiconductor ions are prevented from being implanted into the semiconductor substrate under the first dielectric layer.

9. The method of claim 7, wherein the implanting of the semiconductor ions comprises implanting the semiconductor ions to a depth of about 7 to about 10 nm.

10. The method of claim 9, wherein the implanting of the semiconductor ions comprises implanting the semiconductor ions with an ion implantation energy of about 1 to about 50 KeV.

11. The method of claim 1, wherein the thermally treating of the multi-layered dielectric structure is performed at a temperature of about 700 to about 900 C. for about 1 to about 60 minutes.

12. The method of claim 1, wherein the forming of the multi-layered dielectric structure further comprises forming a third dielectric layer including an ion implantation layer on the second dielectric layer without the ion implantation layer.

13. The method of claim 12, wherein the forming of the nanocrystals comprises forming the nanocrystals in the first through third dielectric layers by performing thermal treatment.

14. The method of claim 1, after forming of the nanocrystals in the first and second dielectric layers, further comprising:
forming a third dielectric layer on the second dielectric layer;
forming an ion implantation layer by implanting semiconductor ions into a charge storage region of the third dielectric layer; and
forming nanocrystals in the third dielectric layer by thermally treating the resultant product.

15. The method of claim 1, wherein the forming of the multi-layered dielectric structure comprises alternately stacking the first dielectric layer with the ion implantation layer and the second dielectric layer without the ion implantation layer.

16. A semiconductor memory device comprising:
source/drain regions formed in a semiconductor substrate to be spaced apart from each other;
a channel region disposed between the source/drain regions;
a multi-layered dielectric structure having two or more dielectric layers stacked on the channel region;
nanocrystals formed in the respective dielectric layers of the multi-layered dielectric structure; and
a gate electrode formed on the multi-layered dielectric structure.

17. The semiconductor memory device of claim 16, wherein the multi-layered dielectric structure is constructed such that adjacent dielectric layers are made of materials having different dielectric constants with respect to each other.

18. The semiconductor memory device of claim 17, wherein the one or more dielectric layers comprise at least one material selected from the group consisting of SiO₂, SiON, Al₂O₃, ZrO₂, HfO₂ and La₂O₃.

19. The semiconductor memory device of claim 16, wherein the respective dielectric layers of the multi-layered dielectric structure have a thickness of about 1 to about 50 nm.

20. The semiconductor memory device of claim 16, wherein the nanocrystals are positioned at a central portion of each of the respective dielectric layers in the planar direction of the semiconductor substrate.

21. The semiconductor memory device of claim 16, wherein the multi-layered dielectric structure includes first and second dielectric layers sequentially stacked, and wherein the density of the nanocrystals formed in the first dielectric layer is higher than that of the nanocrystals formed in the second dielectric layer.

22. The semiconductor memory device of claim 21, wherein the nanocrystals in the first dielectric layer are positioned to be spaced about 1 to about 7 nm apart from a surface of the semiconductor substrate.

23. The semiconductor memory device of claim 16, wherein the nanocrystals are silicon (Si) or germanium (Ge) nanocrystals.
